(19) United States
(12) Patent Application Publication
(10) Pub. No.: US 2026/0293118 A1
(43) Pub. Date: Sep. 24, 2026

(54) SEMICONDUCTOR DEVICES HAVING FENCE STRUCTURE

(71) Applicant: Samsung Electronics Co., Ltd., Suwon-si (KR)

(72) Inventors: Jongin Kang, Suwon-si (KR); Jieun Lee, Suwon-si (KR); Hoin Lee, Suwon-si (KR)

(73) Assignee: Samsung Electronics Co., Ltd., Suwon-si (KR)

(21) Appl. No.: 19/571,431

(22) Filed: Mar. 18, 2026

(30) Foreign Application Priority Data
Mar. 21, 2025 (KR) 10-2025-0036372

(51) Int. Cl. H10B 12/00

(52) U.S. Cl. CPC H10B 12/485; H10B 12/0335; H10B 12/315; H10B 12/50

(57) ABSTRACT

A semiconductor device includes a substrate including an active region, a cell gate structure disposed within the substrate and extending in a first direction across the active region, bit line structures intersecting the cell gate structure and extending in a second direction, spacer structures covering both sidewalls of the bit line structures, a buried contact structure disposed in a lower portion of a space between the spacer structures, and connected to the active region, a landing pad structure disposed in an upper portion of the space between the spacer structures, on the buried contact structure, and a fence structure penetrating the buried contact structure and the landing pad structure and extending in the first direction, and overlapping the cell gate structure in a vertical direction.

### CROSS-REFERENCE TO RELATED APPLICATIONS

This present application claims priority to and the benefit under 35 U.S.C. § 119(a)-(d) of Korean Patent Application No. 10-2025-0036372, filed on Mar. 21, 2025, in the Korean Intellectual Property Office, the entire disclosure of which is incorporated herein by reference.

### FIELD

The present disclosed concept relates to semiconductor devices including a fence structure.

### BACKGROUND

As demand for high performance, high speed, and/or multifunctionality of semiconductor devices increases, the integration of semiconductor devices is increasing. In manufacturing semiconductor devices with fine patterns corresponding to the trend toward high integration of semiconductor devices, it is necessary to implement patterns having fine widths or fine spacings.

### SUMMARY

Example embodiments provide a semiconductor device with improved electrical characteristics and reliability.

Example embodiments provide a method of manufacturing a semiconductor device with improved manufacturing process efficiency.

In example embodiments, a semiconductor device includes a substrate including an active region; a cell gate structure disposed within the substrate and extending in a first direction across the active region; bit line structures intersecting the cell gate structure and extending in a second direction, intersecting the first direction; spacer structures covering both sidewalls of the bit line structures; a buried contact structure disposed in a lower portion of a space between the spacer structures, on the substrate, and connected to the active region; a metal-semiconductor compound layer disposed on the buried contact structure; a landing pad structure disposed in an upper portion of the space between the spacer structures, on the metal-semiconductor compound layer and the bit line structures; and a fence structure extending in the first direction by penetrating through the buried contact structure, the metal-semiconductor compound layer and the landing pad structure, and overlapping the cell gate structure in a vertical direction intersecting the first direction and the second direction. The landing pad structure includes a conductive barrier layer disposed on side surfaces of the spacer structures protruding on the metal-semiconductor compound layer, and a conductive pad pattern disposed on the conductive barrier layer and in contact with the fence structure.

In example embodiments, a semiconductor device includes a substrate including an active region; a cell gate structure disposed within the substrate and extending in a first direction across the active region; bit line structures intersecting the cell gate structure and extending in a second direction, intersecting the first direction; spacer structures covering both sidewalls of the bit line structures; a buried contact structure disposed in a lower portion of a space between the spacer structures, on the substrate, and connected to the active region; a landing pad structure disposed in an upper portion of the space between the spacer structures, on the buried contact structure and the bit line structures; and a fence structure penetrating the buried contact structure and the landing pad structure and extending in the first direction, and overlapping the cell gate structure in a vertical direction intersecting the first direction and the second direction. A width of the fence structure in the second direction becomes narrower as it goes downwardly, and a width of the landing pad structure in the second direction becomes wider as it goes downwardly.

In example embodiments, a semiconductor device includes a substrate including a cell area and a peripheral circuit area; a cell active region disposed on the substrate in the cell area; a peripheral active region disposed on the substrate in the peripheral circuit area; a cell gate structure disposed within the substrate in the cell area and extending in a first direction across the cell active region; bit line structures intersecting the cell gate structure and extending in a second direction, intersecting the first direction; spacer structures covering both sidewalls of the bit line structures; a buried contact structure disposed in a lower portion of a space between the spacer structures and on the cell gate structure, on the substrate, and connected to the active region; a metal-semiconductor compound layer on the buried contact structure; a landing pad structure disposed in an upper portion of the space between the spacer structures, on the metal-semiconductor compound layer and the bit line structures; a fence structure extending in the first direction while penetrating the buried contact structure, the metal-semiconductor compound layer, and the landing pad structure, and overlapping the cell gate structure in a vertical direction intersecting the first direction and the second direction; a peripheral gate structure disposed on the substrate in the peripheral circuit area; a peripheral contact plug disposed adjacent to the peripheral gate structure and connected to the peripheral active region; and a peripheral interconnection layer on the peripheral contact plug. The landing pad structure includes a conductive barrier layer disposed on side surfaces of the spacer structures protruding on the metal-semiconductor compound layer, and a conductive pad pattern disposed on the conductive barrier layer and in contact with the fence structure, and the peripheral contact plug includes a peripheral conductive pattern, a peripheral barrier layer surrounding a side surface and a lower surface of the peripheral conductive pattern, and a peripheral metal-semiconductor compound pattern on a lower surface of the peripheral barrier layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view illustrating a semiconductor device according to example embodiments;

FIG. 2A is an enlarged view illustrating some components of example embodiments of region A of the semiconductor device of FIG. 1;

FIG. 2B is an enlarged view illustrating other components of example embodiments of region A of the semiconductor device of FIG. 1;

FIG. 3A provides cross-sectional views illustrating example embodiments along lines I-I′ and II-II′ of FIG. 2A and FIG. 2B;

FIG. 3B is a cross-sectional view illustrating example embodiments along line III-III′ of FIG. 1;

FIG. 4A is an enlarged view illustrating other components of example embodiments of region A of the semiconductor device of FIG. 1;

FIG. 4B is a cross-sectional view illustrating embodiments along lines IV-IV′ and V-V′ of FIG. 4A; and

FIGS. 5A, 5B, 5C, 6A, 6B, 6C, 7A, 7B, 7C, 8A, 8B, 8C, 8D, 9A, and 9B are drawings illustrating example embodiments of a method of manufacturing the semiconductor device of FIG. 1.

### DETAILED DESCRIPTION

Hereinafter, with reference to the attached drawings, example embodiments will be described in more detail. The same reference numerals are used for the same components in the drawings, and duplicate descriptions of the same components are omitted.

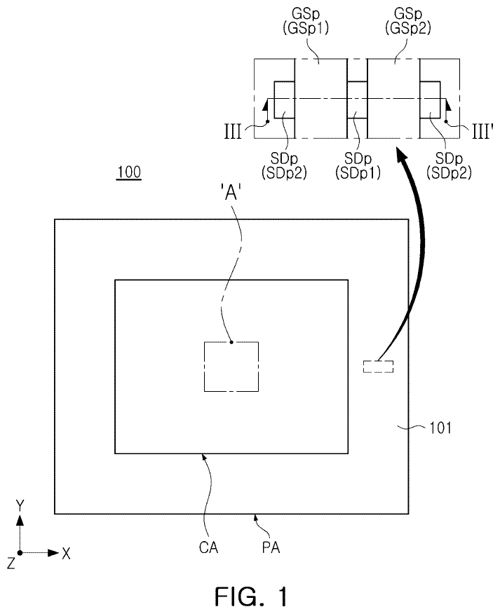

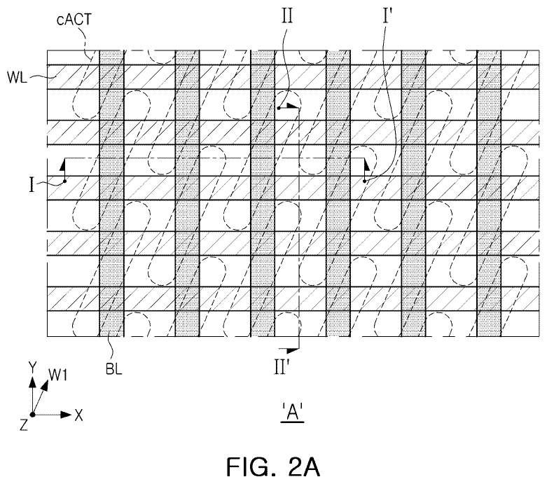

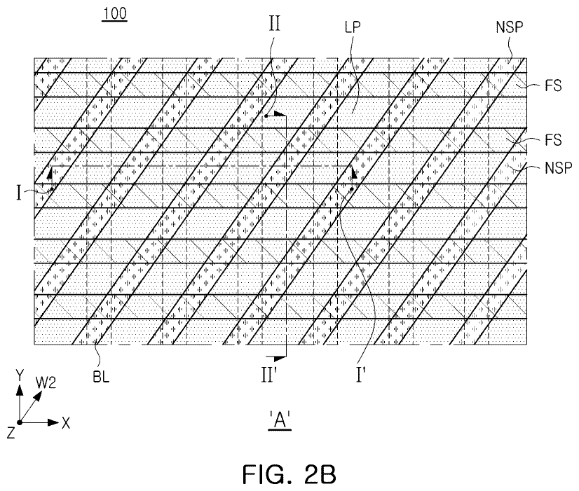

FIG. 1 is a cross-sectional view illustrating a semiconductor device according to example embodiments. FIG. 2A is an enlarged view illustrating some components of example embodiments of region A of the semiconductor device of FIG. 1. FIG. 2B is an enlarged view illustrating other components of example embodiments of region A of the semiconductor device of FIG. 1. FIG. 2A is a cross-sectional view illustrating a cell active region cACT, a bit line BL, and a word line WL disposed in a cell area CA, and FIG. 2B is a cross-sectional view illustrating a landing pad LP, a pad separation pattern NSP, and a fence structure FS disposed in the cell area CA.

Referring to FIG. 1, a semiconductor device 100 may include a substrate 101 including a cell area CA and a peripheral circuit area PA. The peripheral circuit area PA may be disposed to surround the cell area CA. The cell area CA may refer to an area where memory cells of a Dynamic Random Access Memory (DRAM) device are disposed, and the peripheral circuit area PA may be an area where word line drivers, sense amplifiers, row and column decoders, and control circuits are disposed.

Referring to FIG. 1, FIG. 2A, and FIG. 2B, a semiconductor device 100 may include a substrate 101 including a cell active region cACT, word lines WL extending in a first direction (X-direction) within the cell active region cACT of the substrate 101 and spaced apart from each other in a second direction (Y-direction), and bit lines BL extending in the second direction (Y-direction) on the cell active region cACT of the substrate 101 and spaced apart from each other in the first direction (X-direction). The semiconductor device 100 may include a fence structure FS extending in a first direction (X-direction) and overlapping the word line WL in a vertical direction (Z-direction), pad separation patterns NSP disposed on the bit line BL and spaced apart in the first direction (X-direction), and landing pads LP physically separated by the pad separation patterns NSP and the fence structures FS.

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on-insulator (GOI) substrate, a silicon-germanium substrate, or a substrate including an epitaxial layer.

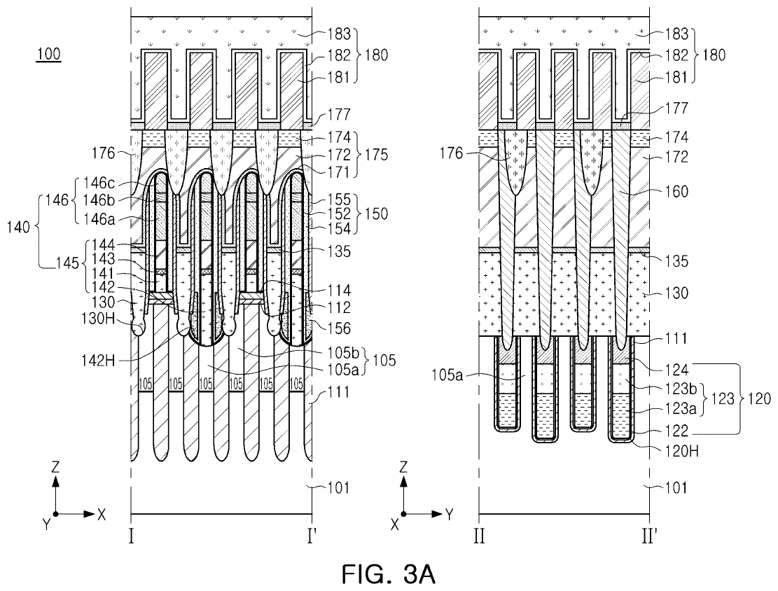

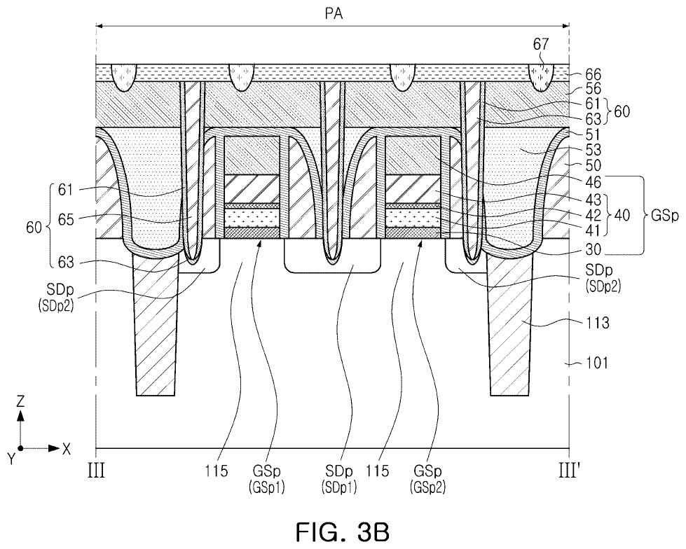

The cell active regions cACT may be defined within the substrate 101 by a cell element isolation pattern (for example, a cell element isolation pattern 111 of FIG. 3A). The cell active region cACT may be in a bar shape and may be disposed in an island shape extending in one direction, for example, in a first diagonal direction (W1 direction), within the substrate 101. The first diagonal direction (W1 direction) may be an inclined direction with respect to the extension direction of the word lines WL and the bit lines BL. The cell active regions cACT may be arranged to be parallel to each other, and the end of one cell active region cACT may be arranged to be adjacent to the center of another cell active region cACT adjacent thereto.

The fence structures FS may extend in the first direction (X-direction) and may be spaced apart from each other in the second direction (Y-direction). In an example, each of the fence structures FS may overlap the word line WL in the vertical direction (Z-direction).

The pad separation patterns NSP may physically separate the landing pads LP. The pad separation patterns NSP may extend in the second diagonal direction (W2 direction) and may be disposed alternately in the first direction (X-direction). The second diagonal direction (W2 direction) may be between the first direction (X-direction) and the second direction (Y-direction).

FIG. 3A is a cross-sectional view illustrating example embodiments along lines I-I′ and II-II′ of FIGS. 2A and 2B. FIG. 3B is a cross-sectional view illustrating example embodiments along lines III-III′ of FIG. 1.

Referring to FIG. 3A, the cell area CA of the semiconductor device 100 may include a cell active region 105, a cell element isolation pattern 111 defining the cell active region 105, cell gate structures 120 extending in a first direction (X-direction) across the cell active region 105 in the substrate 101, bit line structures 140 extending while intersecting the cell gate structure 120, on the substrate 101, and each including a bit line 145, spacer structures 150 covering both sidewalls of the respective bit line structures 140, buried contact structures 130 disposed between the bit line structures 140, a metal-semiconductor compound layer 135 disposed on the buried contact structure 130, landing pad structures 175 disposed on the metal-semiconductor compound layer 135, and a fence structure 160 extending in the first direction (X-direction) and penetrating the landing pad structure 175, the metal-semiconductor compound layer 135, and the buried contact structure 130. The semiconductor device 100 may further include a pad separation pattern 176 physically separating the landing pad structures 175, and a capacitor structure 180.

The cell active regions cACT may be defined within the substrate 101 by the cell element isolation pattern 111. The cell active region cACT may have first and second impurity regions 105a and 105b of a predetermined depth from the upper surface of the substrate 101. The first and second impurity regions 105a and 105b may be spaced apart from each other. The first and second impurity regions 105a and 105b may be provided as source/drain regions of a transistor formed by the cell gate structure 120. For example, a drain region may be formed between two cell gate structures 120 crossing one cell active region cACT, and a source region may be formed on the outside of each of the two cell gate structures 120. The source region and the drain region are formed by the first and second impurity regions 105a and 105b by doping or ion implantation of substantially the same impurities, and may be referred to interchangeably depending on the circuit configuration of the transistor to be finally formed. The impurities may include dopants having a conductive type opposite to that of the substrate 101. In example embodiments, the depths of the first and second impurity regions 105a and 105b in the source region and the drain region may be different from each other. The cell active region 105 may correspond to the cell active region cACT of FIG. 1.

The cell element isolation pattern 111 may be formed by a shallow trench element isolation (STI) process. The cell element isolation pattern 111 may surround the cell active regions 105 and electrically isolate the same from each other. The cell element isolation patterns 111 may be made of an insulating material, for example, silicon oxide, silicon nitride, or a combination thereof. The cell element isolation pattern 111 may include a plurality of regions having different bottom depths according to the width of the trench in which the substrate 101 is etched. The upper surface of the cell element isolation pattern 111 may be coplanar with the upper surface of the substrate 101, and the lower surface of the cell element isolation pattern 111 may be disposed at a lower level than the lower surface of the cell gate structure 120.

The cell gate structures 120 may each extend in a first direction (X-direction) and be spaced apart from each other in a second direction (Y-direction). The cell gate structures 120 may be embedded in the substrate 101. For example, each of the cell gate structures 120 may be disposed within a cell gate trench 120H formed within the substrate 101. The cell gate structure 120 may include a cell gate dielectric layer 122 disposed within the cell gate trench 120H, a cell gate electrode layer 123, and a cell gate capping layer 124 on the cell gate electrode layer 123. The cell gate dielectric layer 122 may be conformally disposed on an inner wall of the cell gate trench 120H. The cell gate electrode layer 123 may be disposed in the lower portion of the cell gate trench 120H, and the cell gate capping layer 124 may be disposed in the upper portion of the cell gate trench 120H and may fill the cell gate trench 120H.

The cell gate dielectric layer 122 may include silicon oxide or a material having a high dielectric constant. The cell gate dielectric layer 122 may be a layer formed by oxidizing the cell active region 105 or a layer formed by deposition.

The cell gate electrode layer 123 may include a first cell gate electrode layer 123a and a second cell gate electrode layer 123b on the first cell gate electrode layer 123a. The first cell gate electrode layer 123a may include at least one of titanium (Ti), titanium nitride (TiN), tantalum (Ta), tantalum nitride (TaN), tungsten (W), tungsten nitride (WN), and aluminum (Al). In example embodiments, the first cell gate electrode layer 123a may include titanium nitride (TiN). The second cell gate electrode layer 123b may include polysilicon. The cell gate capping layer 124 may include silicon nitride. The cell gate structure 120 may correspond to the word line WL of FIG. 1.

The first and second buffer layers 112 and 114 may be disposed on the substrate 101 to cover the cell active regions 105 and the cell element isolation pattern 111. The first and second buffer layers 112 and 114 may include at least one of silicon oxide, silicon nitride, silicon oxynitride, or combinations thereof. Each of the first and second buffer layers 112 and 114 may include a single material or a composite material including two or more materials. The second buffer layer 114 may have a higher permittivity than that of the first buffer layer 112.

The bit line structures 140 may respectively extend in the second direction (Y-direction) and may be spaced apart from each other in the first direction (X-direction). Each of the bit line structures 140 may have a bar shape extending in the second direction (Y-direction). The bit line structure 140 may include a bit line 145 and a bit line capping layer 146 on the bit line 145.

The bit line 145 may include a first conductive layer 141, a second conductive layer 143, and a third conductive layer 144 that are sequentially disposed on the first and second buffer layers 112 and 114, and the bit line 145 may further include a bit line contact plug 142 that is disposed under the first conductive layer 141 and connected to the first impurity region 105a. The bit line contact plug 142 may be located within the bit line contact hole 142H. The bit line contact hole 142H may penetrate the first and second buffer layers 112 and 114 and may be formed to expose the first impurity region 105a in the cell active region 105. The bit line contact hole 142H may extend into the first impurity region 105a of the cell active region 105. The bit line contact plug 142 may electrically connect the cell active region 105 to the bit line structure 140. The buried insulating pattern 156 may fill a portion of the bit line contact hole 142H and surround a side surface of the bit line contact plug 142. The buried insulating pattern 156 may include silicon nitride.

The first conductive layer 141 may include polysilicon. The second conductive layer 143 may include a metal-semiconductor compound. The metal-semiconductor compound may be, for example, a layer that silicides a portion of the first conductive layer 141. For example, the metal-semiconductor compound may include cobalt silicide (CoSi), titanium silicide (TiSi), nickel silicide (NiSi), tungsten silicide (WSi), or other metal silicides, or may include a nitride such as TiSiN. The third conductive layer 144 may include a metal material such as titanium (Ti), tantalum (Ta), tungsten (W), and aluminum (Al). The bit line contact plug 142 may include the same material as the first conductive layer 141.

The bit line capping layer 146 may include a first capping layer 146a, a second capping layer 146b, and a third capping layer 146c that are disposed on the bit line 145. The side surfaces of the first and second capping layers 146a and 146b may be coplanar with the side surface of the bit line 145. The first capping layer 146 a, the second capping layer 146b, and the third capping layer 146c may include silicon oxide, silicon nitride, silicon oxynitride, or combinations thereof, and may include, for example, silicon nitride. The bit line structure 140 may correspond to the bit line BL of FIG. 1.

The spacer structures 150 may be disposed on both sidewalls of each of the bit line structures 140. The spacer structures 150 may cover both sidewalls of the bit line structure 140. Each of the spacer structures 150 may include a first spacer 152, a second spacer 154, and a third spacer 155. The first spacer 152 may be conformally disposed along the sidewall and upper surface of the bit line structure 140, the upper surface of the first and second buffer layers 112 and 114, and the lower surface of the buried insulating pattern 156 within the bit line contact hole 142H. The second spacer 154 may be disposed on the first spacer 152 to extend between the buried insulating pattern 156 and the first spacer 152 to fill the bit line contact hole 142H. The third spacer 155 may be disposed on the side surface of the second spacer 154 so as to extend in the vertical direction (Z-direction), but may be disposed on the outer side surface of the buried insulating pattern 156. In an example, the first, second, and third spacers 152, 154 and 155 may include silicon oxide, silicon nitride, silicon oxynitride, or combinations thereof.

The buried contact structures 130 may be disposed between adjacent bit line structures 140 and may contact the spacer structures 150. The buried contact structure 130 may be disposed between the bit line structures 140 on the cell gate structures 120.

The buried contact structure 130 is disposed on the cell gate structures 120 and may be disposed in the lower portion between the spacer structures 150.

The buried contact hole 130H may have an internal space limited by the spacer structures 150 spaced apart in the first direction (X-direction) and the cell active region 105. The buried contact hole 130H may be formed by removing the first and second buffer layers 112 and 114 and a portion of the cell active region 105, and the buried contact structure 130 may be disposed within the buried contact hole 130H. The lower surface of the buried contact structure 130 may have a shape according to the surface profile of the buried contact hole 130H. The buried contact structure 130 may be electrically connected to the second impurity region 105b of the cell active region 105 of the substrate 101. In an example, the width of the buried contact structure 130 disposed on the cell gate structures 120 in the second direction (Y-direction) may become narrower as it goes upwardly. In example embodiments, the upper surface of the buried contact structure 130 may be disposed at a level lower than the upper surface of the bit line structure 140, and the lower surface of the buried contact structure 130 may be disposed at a level lower than the upper surface of the substrate 101. A portion of the lower surface of the buried contact structure 130 may be in contact with the upper surface of the cell gate dielectric layer 122 of the cell gate structure 120 and the upper surface of the cell gate capping layer 124. In an example, the buried contact structure 130 may be made of a conductive material, and may include at least one of polysilicon (Si), titanium (Ti), titanium nitride (TiN), tantalum (Ta), tantalum nitride (TaN), tungsten (W), tungsten nitride (WN), and aluminum (Al). In example embodiments, the buried contact structure 130 may include doped polysilicon and may include n-type impurities such as phosphorus (P), arsenic (As), and antimony (Sb).

The metal-semiconductor compound layer 135 may be disposed on the upper surface of the buried contact structure 130. The metal-semiconductor compound layer 135 may be disposed on the upper surface of the buried contact structure 130 that is exposed through the space between the spacer structures 150. In an example, the metal-semiconductor compound layer 135 may include cobalt silicide (CoSi), titanium silicide (TiSi), nickel silicide (NiSi), tungsten silicide (WSi), or other metal silicides.

The landing pad structures 175 may be disposed on the metal-semiconductor compound layer 135. The landing pad structures 175 may respectively be disposed on the metal-semiconductor compound layer 135 exposed through the space between the spacer structures 150. Each of the landing pad structures 175 may include a conductive barrier layer 171 covering the sidewalls and the upper surfaces of the spacer structures 150 exposed on the metal-semiconductor compound layer 135, a first conductive pad pattern 172 disposed on the upper surface of the conductive barrier layer 171 and the metal-semiconductor compound layer 135, and a second conductive pad pattern 174 on the first conductive pad pattern 172. The conductive barrier layer 171 may be conformally disposed according to the surface profiles of the sidewalls and the upper surfaces of the spacer structures 150. In an example, a width of the landing pad structure 175 in the second direction (Y-direction) may become narrower toward the top. The first conductive pad pattern 172 may include a first conductive material, and the second conductive pad pattern 174 may include a second conductive material different from the first conductive material.

An upper surface of the first conductive pad pattern 172 may be disposed at a higher level than the upper surface of the bit line structure 140, and the height of the first conductive pad pattern 172 in the vertical direction (Z-direction) may be greater than the height of the second conductive pad pattern 174 in the vertical direction (Z-direction). In an example, the conductive barrier layer 171 may not overlap the cell gate structure 120 in the vertical direction (Z-direction).

The conductive barrier layer 171 may include at least one of a metal nitride, for example, titanium nitride (TiN), tantalum nitride (TaN), and tungsten nitride (WN). The first conductive pad pattern 172 and the second conductive pad pattern 174 may be formed of doped polysilicon, a metal, a metal silicide, a conductive metal nitride, or combinations thereof, and for example, may include at least one of titanium (Ti), tantalum (Ta), tungsten (W), and aluminum (Al). In example embodiments, the conductive barrier layer 171 may include titanium nitride (TiN), the first conductive pad pattern 172 may include titanium nitride (TiN), and the second conductive pad pattern 174 may include tungsten (W). In this document, the landing pad structure 175 may correspond to the landing pad LP of FIG. 2B.

An upper surface of the pad separation pattern 176 may be coplanar with the upper surface of the landing pad structure 175. The pad separation pattern 176 may extend downwardly and partially contact the bit line capping layer 146 of the bit line structure 140. The pad separation pattern 176 may spatially separate the landing pad structures 175 from each other in the first direction (X-direction) and electrically insulate each other. In example embodiments, each of the pad separation patterns 176 may contact a side surface of the bit line capping layer 146 of the bit line structure 140 and at least a portion of an upper portion of the spacer structures 150. In an example, the pad separation patterns 176 may contact a side surface of the fence structure 160. The pad separation pattern 176 may correspond to the pad separation pattern NSP of FIG. 2B.

In example embodiments, when viewed in a plan view, each of the pad separation patterns 176 may be in a form that extends in a diagonal direction (for example, the second diagonal direction W2 of FIG. 2B) between the first direction (X-direction) and the second direction (Y-direction).

The fence structures 160 may extend in the first direction (X-direction) and be spaced apart from each other in the second direction (Y-direction). Each of the fence structures 160 may penetrate the landing pad structure 175, the metal-semiconductor compound layer 135, and the buried contact structure 130. The fence structures 160 may respectively overlap the cell gate structure 120 in the vertical direction (Z-direction). The fence structures 160 may spatially separate the landing pad structures 175 from each other in the second direction (Y-direction) and electrically insulate each other.

The side surface of the fence structure 160 may contact the first conductive pad pattern 172, the second conductive pad pattern 174, the metal-semiconductor compound layer 135, and the buried contact structure 130. In example embodiments, the lower surface of the fence structure 160 may be disposed at a level lower than the lower surface of the buried contact structure 130, the upper surface of the substrate 101, and the upper surface of the cell gate structure 120. In an example, the fence structure 160 may penetrate the upper surface of the cell gate capping layer 124 of the cell gate structure 120, such that the lower surface of the fence structure 160 may be embedded in the cell gate capping layer 124. The lower surface of the fence structure 160 may be covered by the cell gate capping layer 124. The upper surface of the fence structure 160 may be coplanar with the upper surface of the landing pad structure 175 and the upper surface of the pad separation pattern 176. The fence structure 160 may correspond to the fence structure FS of FIG. 2B.

The fence structure 160 of the semiconductor device 100 according to example embodiments is formed to extend in the first direction (X-direction) while penetrating the buried contact structure 130, the metal-semiconductor compound layer 135, and the landing pad structure 175 after the buried contact structure 130, the metal-semiconductor compound layer 135, and the landing pad structure 175 are formed, and thus, may directly contact the first and second conductive pad patterns 172 and 174 of the landing pad structure 175.

The semiconductor device 100 may further include an etch stop layer 177 covering the upper surfaces of the landing pad structure 175, the pad separation pattern 176, and the fence structure 160. The capacitor structure 180 may be disposed on the landing pad structure 175, the pad separation pattern 176, and the fence structure 160.

The capacitor structure 180 may include a lower electrode 181, a capacitor dielectric layer 182, and an upper electrode 183 connected to a landing pad structure 175. The lower electrode 181 may penetrate an etch stop layer 177 and contact an upper surface of the landing pad structure 175. The capacitor dielectric layer 182 may cover the lower electrode 181 and the etch stop layer 177, and the upper electrode 183 may cover the capacitor dielectric layer 182. The capacitor structure 180 may be electrically connected to the landing pad structure 175, the metal-semiconductor compound layer 135, and the buried contact structure 130. The lower electrode 181 and the upper electrode 183 may include at least one of a doped semiconductor, a metal nitride, a metal, and a metal oxide. The lower electrode 181 and the upper electrode 183 may include, for example, at least one of polycrystalline silicon, titanium nitride (TiN), tungsten (W), titanium (Ti), ruthenium (Ru), and tungsten nitride (WN). The capacitor dielectric layer 182 may include, for example, at least one of high-k materials, such as zirconium oxide (ZrO₂), aluminum oxide (Al₂O₃), and hafnium oxide (Hf₂O₃).

Referring to FIG. 3B, the peripheral circuit area PA of the substrate 101 may include a peripheral active region 115, a peripheral element isolation pattern 113 that defines the peripheral active region 115, a peripheral gate structure GSp disposed on the substrate 101, peripheral gate spacers 50 disposed on both sidewalls of the peripheral gate structure GSp, peripheral source/drain regions SDp disposed within an upper region of the peripheral active region 115, a peripheral contact plug 60 disposed on one side of the peripheral gate structure GSp and connected to the peripheral source/drain regions SDp, and a peripheral interconnection layer 66 disposed on the peripheral contact plug 60 and connected to the peripheral contact plug 60.

In example embodiments, the peripheral circuit area PA of the substrate 101 may further include a peripheral gate capping layer 51 conformally formed on the peripheral gate structure GSp, the peripheral gate spacers 50 and the peripheral element isolation pattern 113, first peripheral interlayer insulating layer 53 disposed on the peripheral active region 115 and covering the peripheral gate capping layer 51, a second peripheral interlayer insulating layer 56 disposed on the first peripheral interlayer insulating layer 53, and an interconnection separation pattern 67 penetrating the peripheral interconnection layer 66.

The peripheral element isolation pattern 113 may extend downwardly from the upper surface of the substrate 101. The peripheral element isolation pattern 113 may define the peripheral active region 115. The peripheral element isolation pattern 113 may surround peripheral active regions 115 and separate the same from each other. The peripheral element isolation pattern 113 may include an insulating material. The peripheral element isolation pattern 113 may include silicon oxide, silicon nitride, silicon oxynitride, or combinations thereof, and may be formed of a single layer or multiple layers.

The peripheral source/drain regions SDp may include a first peripheral source/drain region SDp1 and a second peripheral source/drain region SDp2. A channel region may be disposed between the first peripheral source/drain region SDp1 and the second peripheral source/drain region SDp2.

The peripheral gate structure GSp may be disposed on the peripheral active region 115. In an example, the peripheral gate structure GSp may be disposed on the channel region between the first peripheral source/drain region SDp1 and the second peripheral source/drain region SDp2. In an example, the peripheral gate structure GSp may include a first peripheral gate structure GSp1 and a second peripheral gate structure GSp2 spaced apart from the first peripheral gate structure GSp1 in a first direction (X-direction). In an example, each of the peripheral gate structures GSp may include a peripheral gate dielectric layer 30, the peripheral gate electrode 40, and a peripheral gate capping pattern 46, sequentially stacked in a vertical direction (Z-direction).

The peripheral gate dielectric layer 30 may be disposed on a channel region disposed between the first peripheral source/drain region SDp1 and the second peripheral source/drain region SDp2. The peripheral gate dielectric layer 30 may include at least one of silicon oxide and a high-k dielectric. The high-k dielectric may have a dielectric constant greater than a dielectric constant of silicon oxide. For example, the peripheral gate dielectric layer 30 may include at least one of silicon oxide, hafnium oxide (HfO), a hafnium-based oxide (Hf-based oxide), aluminum oxide (AIO), aluminum-based oxide (Al-based oxide), lanthanum oxide (LaO), a lanthanum-based oxide (La-based oxide), magnesium oxide (MgO), and magnesium oxide (Mg-based oxide).

The peripheral gate electrode 40 may include a first conductive pattern 41, a second conductive pattern 42, and a third conductive pattern 43 that are disposed on the peripheral gate dielectric layer 30 and are sequentially stacked in a vertical direction (Z-direction). The first conductive pattern 41 may include at least one conductive layer. For example, the first conductive pattern 41 may include at least one of doped polysilicon, TIN, TiAl, TiAlC, TiAlN, TaN, TaAlC, and TaAlN. The second conductive pattern 42 may include a titanium silicon nitride (TiSiN) layer. The third conductive pattern 43 may include a tungsten (W) layer.

The peripheral gate capping pattern 46 may be disposed on the peripheral gate electrode 40. The peripheral gate capping pattern 46 may include an insulating material, for example, silicon nitride.

The peripheral gate spacer 50 may be disposed on a sidewall of the peripheral gate structure GSp, and the peripheral gate spacer 50 may cover sidewalls of the peripheral gate dielectric layer 30, the first conductive pattern 41, the second conductive pattern 42, and the third conductive pattern 43. The peripheral gate spacer 50 may include at least one of silicon oxide and a low-k dielectric. The low-k dielectric may have a dielectric constant lower than a dielectric constant of silicon oxide. In an example, the peripheral gate spacer 50 vertically overlaps the peripheral source/drain regions SDp, and a side surface of the peripheral gate spacer 50 may be covered by a peripheral gate capping layer 51.

The peripheral gate capping layer 51 may extend between the peripheral gate spacer 50 and the peripheral gate dielectric layer 30, onto the sidewall of the peripheral gate structure GSp and the peripheral gate capping pattern 46, to cover the upper surface of the peripheral gate capping pattern 46 and the side surface of the peripheral gate spacer 50.

The first peripheral interlayer insulating layer 53 may fill the space between the peripheral gate spacers 50 on the substrate 101, and the first peripheral interlayer insulating layer 53 may contact the peripheral gate capping layer 51. The upper surface of the first peripheral interlayer insulating layer 53 may be coplanar with the upper surface of the peripheral gate capping layer 51. The second peripheral interlayer insulating layer 56 may be disposed on the first peripheral interlayer insulating layer 53. The first and second peripheral interlayer insulating layers 53 and 56 may include silicon oxide. In this document, the second peripheral interlayer insulation layer 56 may be referred to as a peripheral insulating layer.

The peripheral contact plugs 60 may respectively penetrate the first and second peripheral interlayer insulating layers 53 and 56 and be disposed adjacent to the peripheral gate structure GSp and may be electrically connected to the peripheral source/drain regions SDp. The peripheral contact plug 60 may include a peripheral metal-semiconductor compound pattern 63, a peripheral conductive pattern 65 disposed on the peripheral metal-semiconductor compound pattern 63, and a peripheral barrier layer 61 surrounding the side surface and the lower surface of the peripheral conductive pattern 65 on the peripheral metal-semiconductor compound pattern 63.

In example embodiments, the peripheral metal-semiconductor compound pattern 63 may include cobalt silicide (CoSi), titanium silicide (TiSi), nickel silicide (NiSi), tungsten silicide (WSi), or other metal silicides. In example embodiments, the peripheral metal-semiconductor compound pattern 63 may include the same material as the metal-semiconductor compound layer 135 of the cell area CA. In an example, the peripheral metal-semiconductor compound pattern 63 may be formed in the same process as the metal-semiconductor compound layer 135.

In example embodiments, the peripheral barrier layer 61 may include a metal nitride, for example, at least one of titanium nitride (TiN), tantalum nitride (TaN), and tungsten nitride (WN). The peripheral conductive pattern 65 may include at least one of a conductive material, for example, titanium (Ti), tantalum (Ta), tungsten (W), and aluminum (Al). In an example, the peripheral barrier layer 61 may include the same material as the conductive barrier layer 171 of the landing pad structure 175, and the peripheral conductive pattern 65 may include the same material as the first conductive pad pattern 172 of the landing pad structure 175. The peripheral barrier layer 61 may be formed in the same process as the conductive barrier layer 171, and the peripheral conductive pattern 65 may be formed in the same process as the first conductive pad pattern 172.

The peripheral interconnection layer 66 may be disposed on the second peripheral interlayer insulating layer 56 and connected to the peripheral contact plug 60. The peripheral interconnection layer 66 may include at least one of a conductive material, for example, titanium (Ti), tantalum (Ta), tungsten (W), and aluminum (Al). In an example, the peripheral interconnection layer 66 may include the same material as the second conductive pad pattern 174 of the landing pad structure 175. In an example, the peripheral interconnection layer 66 may be formed in the same process as the second conductive pad pattern 174 of the landing pad structure 175.

The interconnection separation pattern 67 may electrically insulate between adjacent peripheral interconnection layers 66. The interconnection separation pattern 67 may penetrate the peripheral interconnection layer 66, and a lower surface of the interconnection separation pattern 67 may be embedded in the second peripheral interlayer insulating layer 56. The pad separation pattern 176 may include at least one of silicon nitride, silicon oxide, silicon oxynitride, or combinations thereof. The interconnection separation pattern 67 may include the same material as the pad separation pattern 176. The interconnection separation pattern 67 may be formed in the same process as the pad separation pattern 176, but is not limited thereto. For example, the interconnection separation pattern 67 may be formed in a process different from the pad separation pattern 176. In embodiments, the interconnection separation pattern 67 may include a void space (for example, an air gap) containing an air layer.

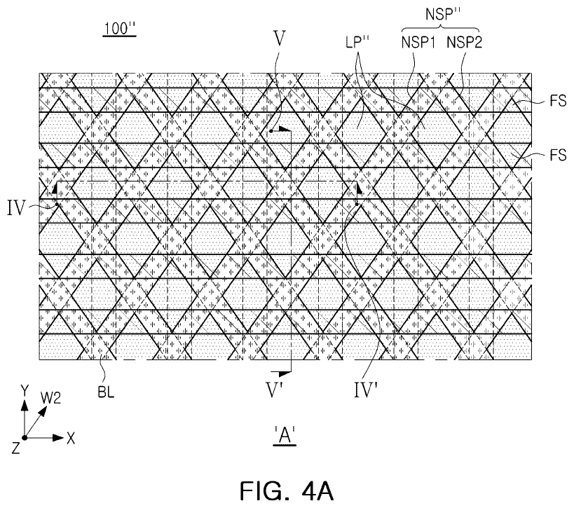

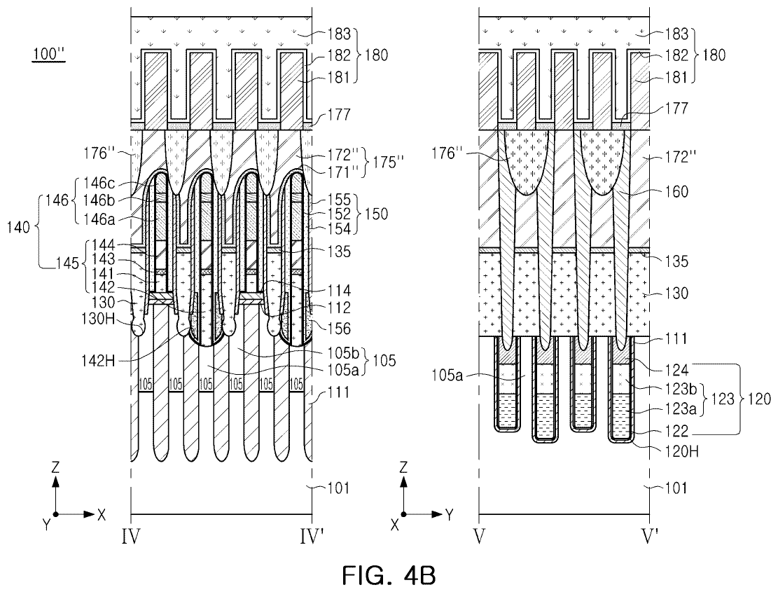

FIG. 4A is an enlarged view illustrating some other configurations according to embodiments of the A region of the semiconductor device of FIG. 1. FIG. 4B is a cross-sectional view illustrating embodiments along lines IV-IV′ and V-V′ of FIG. 4A. FIG. 4A is a cross-sectional view illustrating a landing pad LP″, a pad separation pattern NSP″, and a fence structure FS disposed in a cell area CA.

Referring to FIGS. 4A and 4B, a semiconductor device 100″ may include a landing pad LP″, a pad separation pattern NSP″, and a fence structure FS. The remaining configurations, except for the landing pad LP″ and the pad separation pattern NSP″, may be the same as or correspond to the configurations illustrated in FIG. 3A.

The pad separation patterns NSP″ may physically separate the landing pads LP″. The pad separation pattern NSP″ may include a first pad separation pattern NSP1 and a second pad separation pattern NSP2. The first pad separation pattern NSP1 may be a line shape that extends in a second diagonal direction W2 when viewed in a plane and has a positive slope, and the second pad separation pattern NSP2 may be a line shape that intersects the first pad separation pattern NSP1 and has a negative slope. In an example, the first pad separation pattern NSP1 may have a positive slope of the first size, and the second pad separation pattern NSP2 may have the first size but a negative slope, but is not limited thereto. In example embodiments, the pad separation pattern NSP″ having a mesh structure may be formed as the first pad separation patterns NSP1 and the second pad separation patterns NSP2 intersect and are disposed. The first pad separation patterns NSP1 and the second pad separation patterns NSP2 may physically separate and insulate the landing pads LP″, and the landing pads LP″ may be physically separated by the first pad separation patterns NSP1 and the second pad separation patterns NSP2 and may have an island pattern shape.

The pad separation pattern NSP″ of FIG. 4A may correspond to the pad separation pattern 176″ of FIG. 4B, and the landing pad LP″ of FIG. 4A may correspond to the landing pad structure 175″ of FIG. 4B.

The landing pad structure 175″ may include a conductive barrier layer 171″ and a conductive pad pattern 172″ disposed on an upper surface of the conductive barrier layer 171″ and a metal-semiconductor compound layer 135. The conductive barrier layer 171″ may be conformally disposed according to a surface profile of the sidewalls and the upper surface of the spacer structures 150. The conductive pad pattern 172″ may have a lower surface in contact with the conductive barrier layer 171″ and the metal-semiconductor compound layer 135, an upper surface in contact with the lower electrode 181 of the capacitor structure 180, and a side surface in contact with the fence structure 160. In example embodiments, the conductive barrier layer 171″ may include titanium nitride (TiN), and the conductive pad pattern 172″ may include tungsten (W).

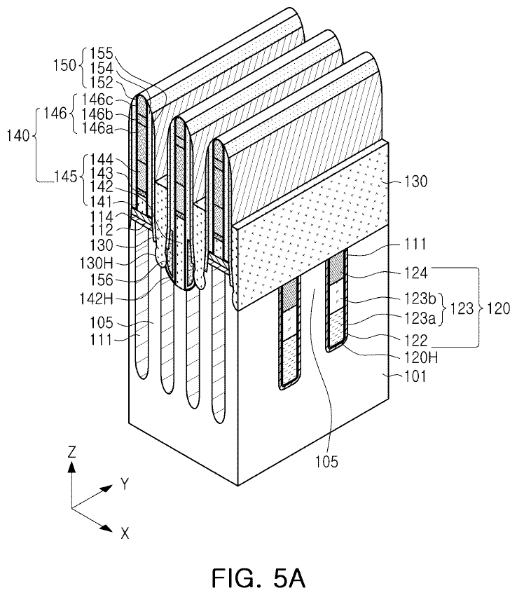

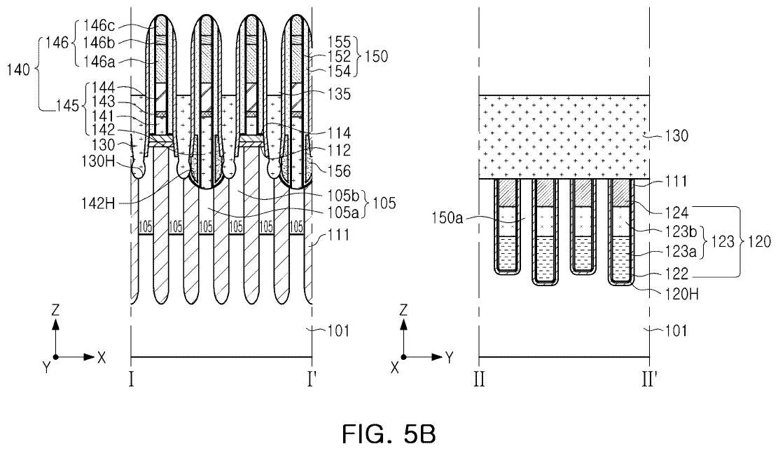

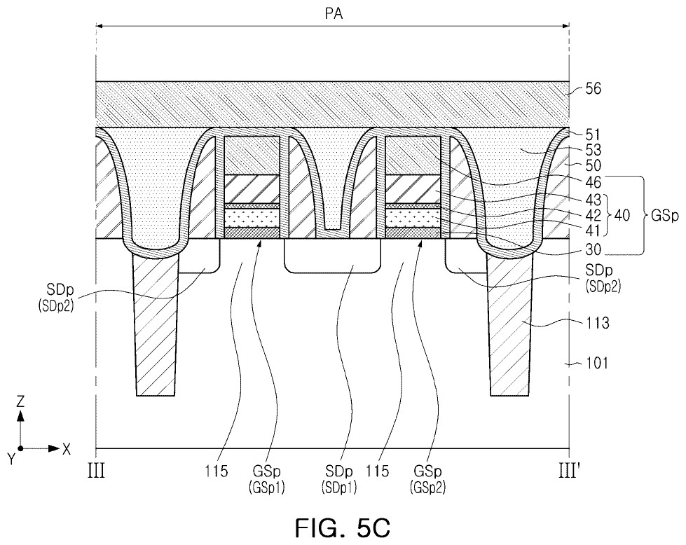

FIGS. 5A, 5B, 5C, 6A, 6B, 6C, 7A, 7B, 7C, 8A, 8B, 8C, 8D, 9A, and 9B are drawings illustrating example embodiments of a method of manufacturing a semiconductor device of FIG. 1. FIGS. 5A, 6A, 7A, 8A, and 9A are perspective views illustrating a method of manufacturing a cell area CA of a semiconductor device. FIGS. 5B, 6B, 7B, 8B, 8C, 8D, and 9B illustrate cross sections taken along lines I-I′ and II-II′ of FIGS. 2A and 2B, respectively, and FIGS. 5C, 6C, and 7C illustrate cross sections taken along line III-III′ of FIG. 1.

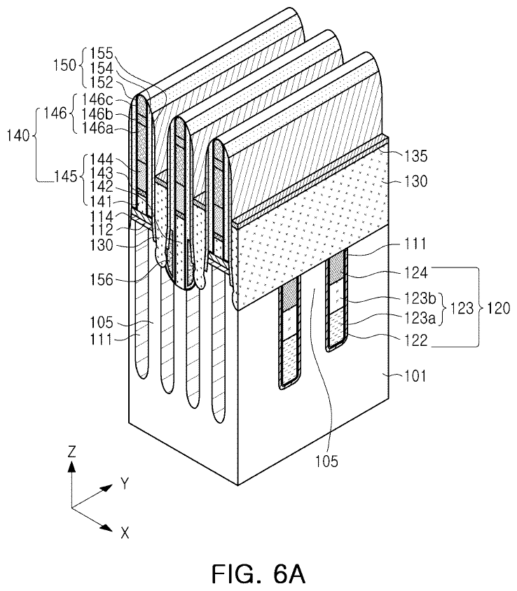

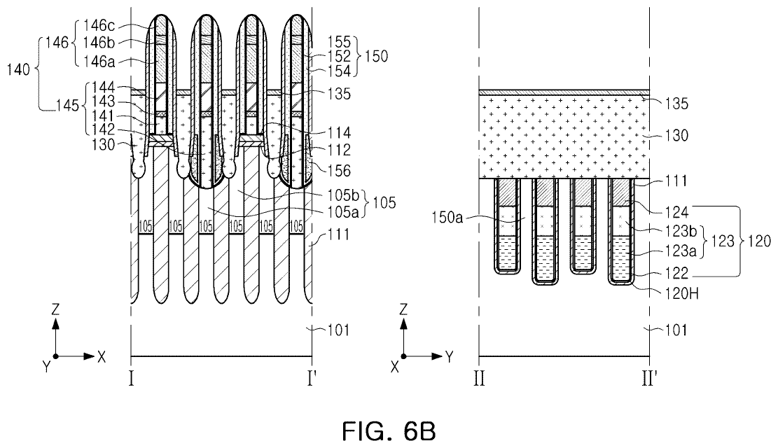

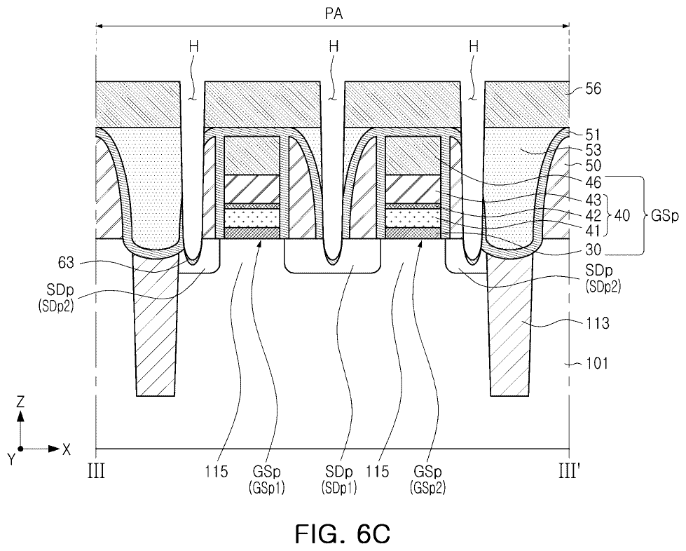

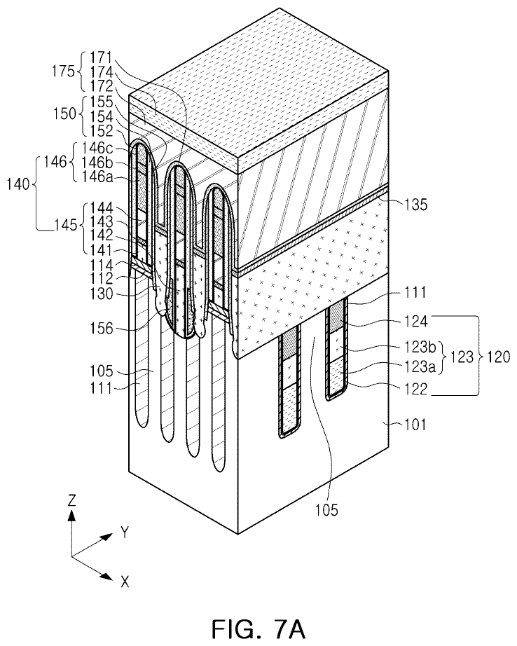

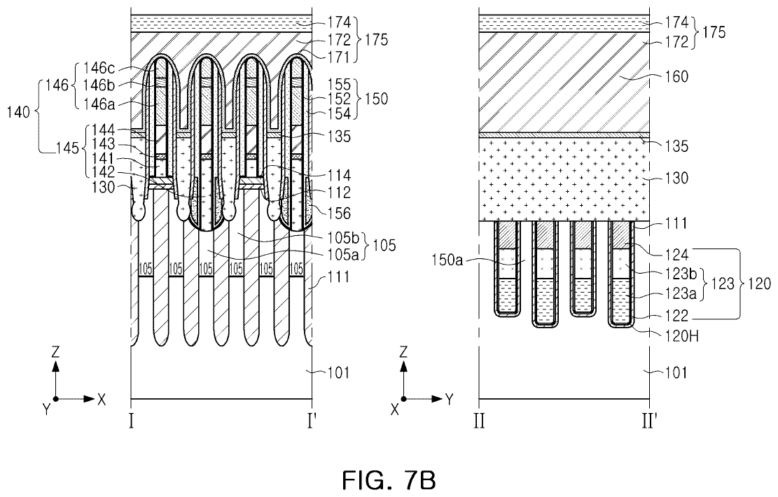

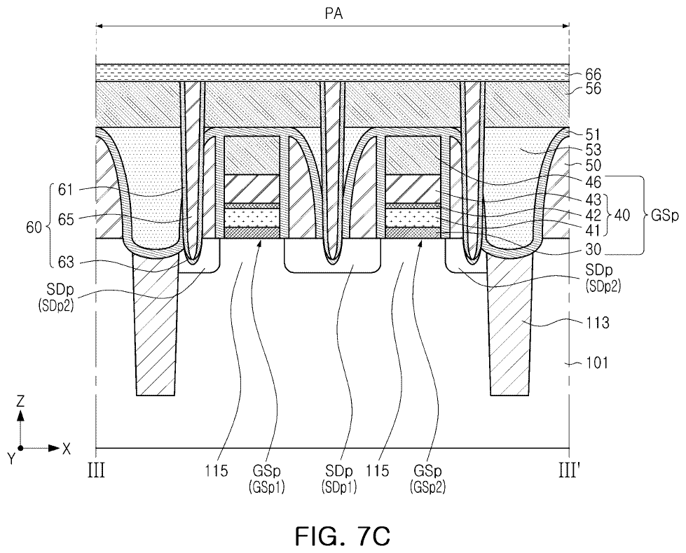

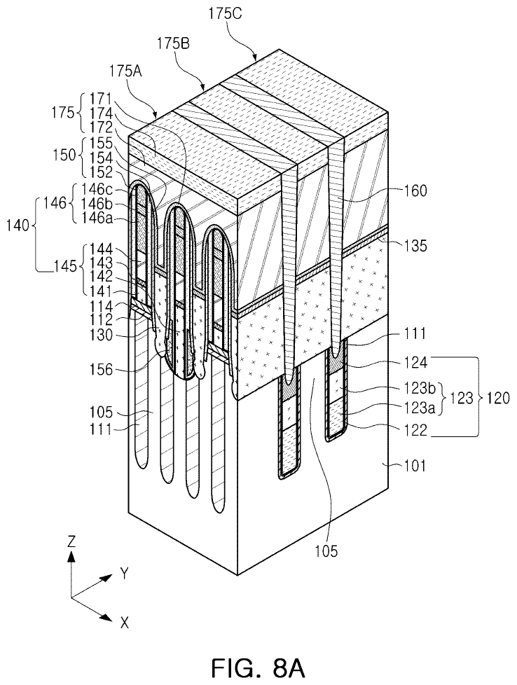

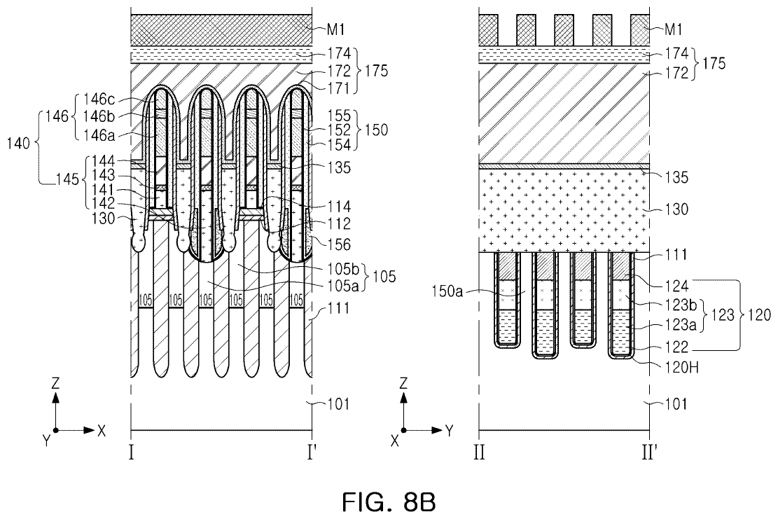

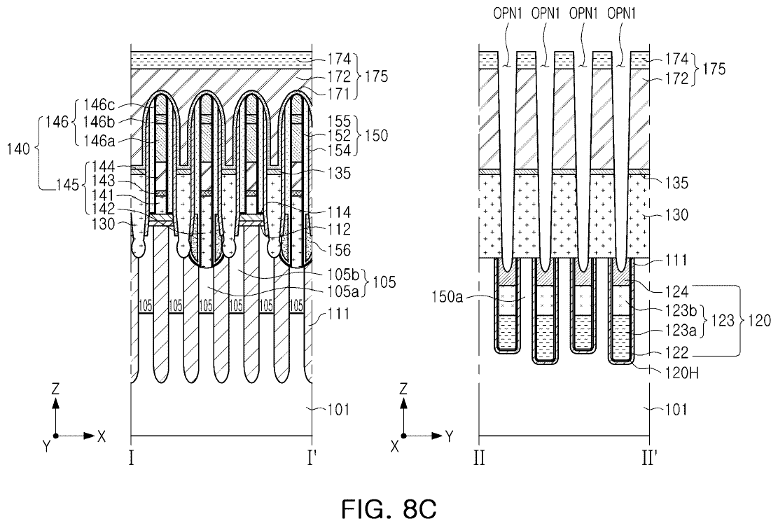

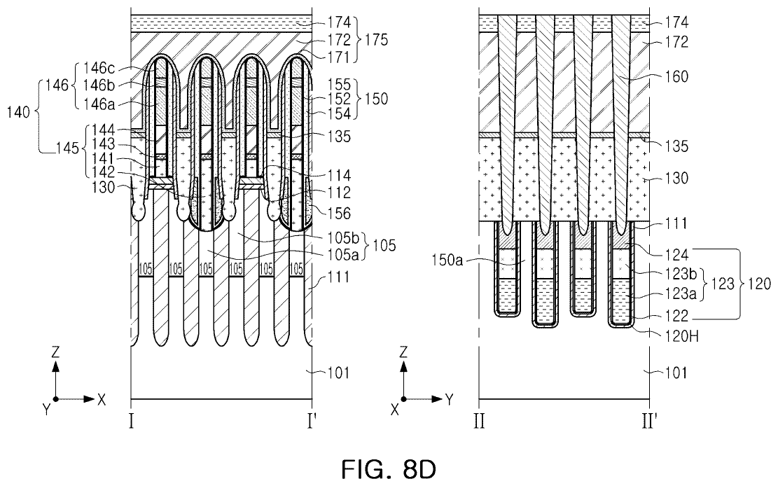

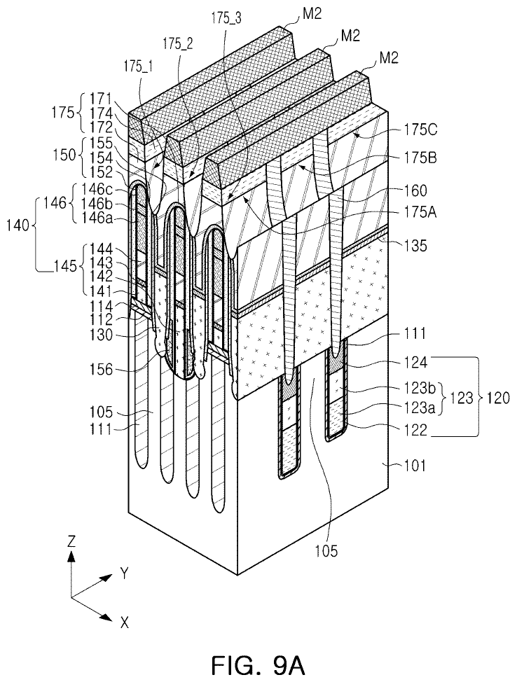

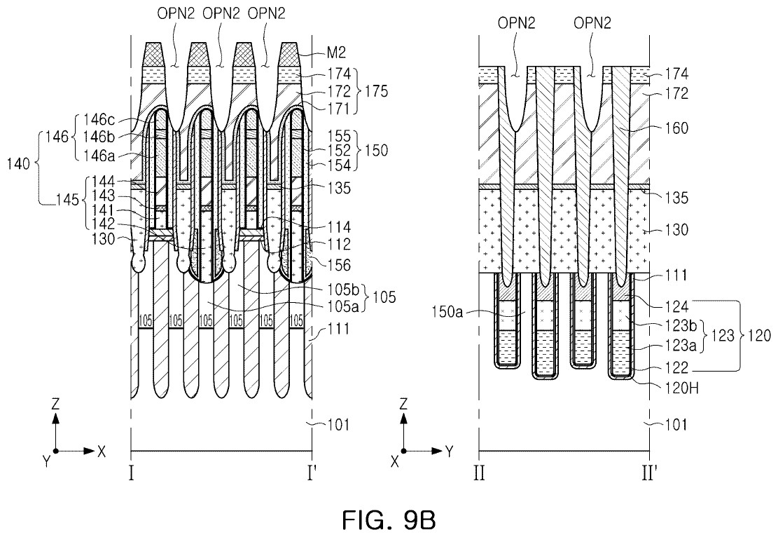

Referring to FIGS. 5A, 5B, 5C, 6A, 6B, 6C, 7A, 7B, 7C, 8A, 8B, 8C, 8D, 9A, and 9B, a method of manufacturing a semiconductor device may include an operation of forming a cell gate structure 120 extending in a first direction (X-direction) within a cell area (for example, cell area CA of FIG. 1) of a substrate 101, an operation of forming bit line structures 140 extending in a second direction (Y-direction) and spaced apart from each other in the first direction (X-direction) and spacer structures 150 covering both sidewalls of the bit line structures 140, on the cell area CA of the substrate 101, an operation of forming a buried contact structure 130 connected to a cell active region 105 of the substrate 101 in a lower portion of a space between the spacer structures 150, on the substrate 101 (refer to FIG. 5A), an operation of forming a metal-semiconductor compound layer 135 on the buried contact structure 130 (refer to FIG. 6A), an operation of forming a landing pad structure 175 in the upper portion of the space between the spacer structures 150 and on the bit line structure 140, on the metal-semiconductor compound layer 135 (refer to FIG. 7A), and an operation of forming a fence structure 160 penetrating the landing pad structure 175, the metal-semiconductor compound layer 135, and the buried contact structure 130 and extending in the first direction (X-direction) (refer to FIG. 8A). In example embodiments, the method of manufacturing a semiconductor device may further include an operation of forming a pad separation pattern 176 that physically separates the landing pad structure 175 in the second direction (Y-direction) (refer to FIG. 9A).

Referring to FIG. 5A and FIG. 5B, cell element isolation patterns 111 defining a cell active region 105 within a cell area (for example, cell area CA of FIG. 1) of a substrate 101 may be formed, and cell gate structures 120 extending in a first direction (X-direction) across the cell active region 105 and spaced apart in a second direction (Y-direction) within the substrate 101 may be formed. The first and second buffer layers 112 and 114 may be formed on the cell element isolation patterns 111, the cell active region 105, and the cell gate structures 120. After forming a bit line contact hole 142H that penetrates the first and second buffer layers 112 and 114 and exposes the first impurity region 105a of the cell active region 105 and extends in the second direction (Y-direction), a bit line contact plug 142, first, second and third conductive layers 141, 143 and 144 and a bit line capping layer 146 that fill the bit line contact hole 142H may be sequentially formed. By forming the bit line contact plug 142, the first, second and third conductive layers 141, 143 and 144 and the bit line capping layer 146, a bit line structure 140 may be formed. Spacer structures 150 that cover both sidewalls of the bit line structure 140 may be formed. The buried contact hole 130H may be formed in a space between the bit line structures 140. The buried contact hole 130H may be limited to a space formed by spacer structures 150 and cell active regions 105 between neighboring bit line structures 140, and the buried contact hole 130H may extend in a second direction (Y-direction). A buried contact structure 130 may be formed within the buried contact hole 130H, and an upper surface of the buried contact structure 130 may be formed to be disposed at a lower level than an upper surface of the bit line structure 140.

Referring to FIG. 5C, a peripheral element isolation pattern 113 defining a peripheral active region 115 within a peripheral circuit area PA of a substrate 101 may be formed, and a peripheral gate structure GSp overlapping a channel region between peripheral source/drain regions SDp on the substrate 101 may be formed. The peripheral gate electrode 40 may be formed in the same process as the first, second, and third conductive layers 141, 143 and 144 of the bit line 145, and the peripheral gate capping pattern 46 may be formed in the same process as the first capping layer 146a of the bit line structure 140. A peripheral gate capping layer 51 covering a sidewall of the peripheral gate structure GSp and peripheral gate spacers 50 may be formed sequentially. A first peripheral interlayer insulating layer 53 may be formed on the peripheral gate capping layer 51 to fill the space between the peripheral gate spacers 50, and a second peripheral interlayer insulating layer 56 may be formed on the first peripheral interlayer insulating layer 53.

Referring to FIGS. 6A and 6B, a metal-semiconductor compound layer 135 may be formed on the buried contact structures 130. The metal-semiconductor compound layer 135 may be formed on the buried contact structures 130 extending in the second direction (Y-direction). The metal-semiconductor compound layer 135 may have a line shape extending in the second direction (Y-direction). The metal-semiconductor compound layer 135 may be a layer in which a portion of the buried contact structures 130 is silicided. However, the present inventive concept is not limited thereto, and the metal-semiconductor compound layer 135 may be formed by various methods. In an example, the metal-semiconductor compound layer 135 may include cobalt silicide (CoSi), titanium silicide (TiSi), nickel silicide (NiSi), tungsten silicide (WSi), or other metal silicides. In example embodiments, the metal-semiconductor compound layer 135 may include cobalt silicide (CoSiₓ).

Referring to FIG. 6C, a peripheral contact hole H may be formed that penetrates the first and second peripheral interlayer insulating layers 53 and 56 and recesses a portion of the substrate 101 to expose a peripheral source/drain region SDp of the substrate 101, and a peripheral metal-semiconductor compound pattern 63 may be formed on a lower surface of the peripheral contact hole H. In an example, at least one of the peripheral contact holes H may penetrate a peripheral gate spacer 50 and a peripheral gate capping layer 51 formed on a sidewall of the peripheral gate structure GSp. The lower surface of the peripheral contact hole H may be formed at a level lower than the upper surface of the substrate 101, and may recess a portion of the peripheral source/drain region SDp concavely. In an example, the peripheral metal-semiconductor compound pattern 63 may be formed in the same process as the metal-semiconductor compound layer 135 of FIGS. 6A and 6B. However, the present inventive concept is not limited thereto, and the peripheral metal-semiconductor compound pattern 63 may be formed by a process that is different from the metal-semiconductor compound layer 135. In an example, the peripheral metal-semiconductor compound pattern 63 may include cobalt silicide (CoSi), titanium silicide (TiSi), nickel silicide (NiSi), tungsten silicide (WSi), or other metal silicides.

Referring to FIGS. 7A and 7B, a landing pad structure 175 covering bit line structures 140 may be formed on the metal-semiconductor compound layer 135. The buried contact structure 130 may be formed on a lower portion between the spacer structures 150, and the landing pad structure 175 may be formed on a remaining portion between the spacer structures 150. A conductive barrier layer 171 may be formed to cover a sidewall and an upper surface of the spacer structures 150 exposed on a metal-semiconductor compound layer 135, a first conductive pad pattern 172 covering an upper surface of the conductive barrier layer 171 and including a first conductive material may be formed, and a second conductive pad pattern 174 including a second conductive material different from the first conductive material may be sequentially formed on the first conductive pad pattern 172. The conductive barrier layer 171, the first conductive pad pattern 172, and the second conductive pad pattern 174 formed sequentially may constitute a landing pad structure 175. In an example, the first conductive pad pattern 172 and the second conductive pad pattern 174 may include different types of conductive materials. However, the present inventive concept is not limited thereto, and in embodiments, the first conductive pad pattern 172 and the second conductive pad pattern 174 may include the same conductive material.

Referring to FIGS. 6C and 7C, a peripheral barrier layer 61 and a peripheral conductive pattern 65 may be sequentially formed on a peripheral metal-semiconductor compound pattern 63 within a peripheral contact hole H. The peripheral barrier layer 61 may be formed on the peripheral metal-semiconductor compound pattern 63 according to the surface profile of the side surface of the peripheral contact hole H. The peripheral conductive pattern 65 may be formed on the peripheral barrier layer 61 and may be surrounded by the peripheral barrier layer 61. The peripheral barrier layer 61 may be formed in the same process as the conductive barrier layer 171 of the landing pad structure 175 of FIGS. 6A and 6B, and may include the same material as the conductive barrier layer 171. The peripheral conductive pattern 65 may be formed in the same process as the first conductive pad pattern 172 of the landing pad structure 175 of FIGS. 6A and 6B, and may include the same material as the first conductive pad pattern 172. By sequentially forming the peripheral metal-semiconductor compound pattern 63, the peripheral barrier layer 61, and the peripheral conductive pattern 65, a peripheral contact plug 60 may be configured.

A peripheral interconnection layer 66 may be formed on the peripheral contact plug 60 and the second peripheral interlayer insulating layer 56. The peripheral interconnection layer 66 may be formed in the same process as the second conductive pad pattern 174 of the landing pad structure 175 of FIGS. 6A and 6B, and may include the same material as the second conductive pad pattern 174.

Referring to FIG. 8A, fence structures 160 may be formed that penetrate the landing pad structure 175, the metal-semiconductor compound layer 135, and the buried contact structure 130 and overlap the cell gate structures 120 in a vertical direction (Z-direction). The fence structures 160 may respectively extend in the first direction (X-direction) and may be spaced apart from each other in the second direction (Y-direction). By forming the fence structures 160 penetrating the landing pad structure 175, the metal-semiconductor compound layer 135, and the buried contact structure 130, the landing pad structure 175 is physically separated by the fence structures 160, and a first landing pad structure 175A, a second landing pad structure 175B, and a third landing pad structure 175C spaced apart in the second direction (Y-direction) may be formed. A method of forming the fence structure 160 will be described with reference to FIGS. 8B, 8C, and 8D.

Referring to FIG. 8B, a first mask pattern M1 may be formed on the landing pad structure 175. The first mask pattern M1 may have a line shape extending in the first direction (X-direction), and the first mask pattern M1 may include first openings that are spaced apart in the second direction (Y-direction) and expose the landing pad structure 175, and each of the first openings may expose the upper surface of the landing pad structure 175 and may overlap the cell gate structure 120 in the vertical direction (Z-direction).

Referring to FIG. 8C, by using the first mask pattern M1, the landing pad structure 175, the metal-semiconductor compound layer 135, the buried contact structure 130, and the substrate 101 may be removed to form first trenches OPN1 that extend in the first direction (X-direction) and are spaced apart in the second direction (Y-direction). The landing pad structure 175, the metal-semiconductor compound layer 135, and the side surface of the buried contact structure 130 may be exposed through the first trenches OPN1. The lower surface of each of the first trenches OPN1 may be disposed at a level lower than the upper surface of the cell gate structure 120. Each of the first trenches OPN1 may overlap the cell gate structure 120 in the vertical direction (Z-direction) and expose a portion of the cell gate capping layer 124. Each of the first trenches OPN1 may concavely recess a portion of the cell gate capping layer 124 of the cell gate structure 120. In this document, the first trench OPN1 may be referred to as a fence structure trench.

Referring to FIG. 8D, an insulating material may be filled in the first trenches OPN1 to form fence structures 160. The insulating material filling the first trenches OPN1 may include silicon nitride. In an example, the fence structure 160 may be in contact with a side surface of a metal-semiconductor compound layer 135 and a side surface of a buried contact structure 130, and when viewed in a plan view, in an area where the first, second, and third landing pad structures 175A, 175B and 175C of FIG. 8A intersect with the cell gate structure 120, the fence structure 160 may be in contact with side surfaces of a conductive barrier layer 171, a first conductive pad pattern 172, and a second conductive pad pattern 174 constituting the first, second, and third landing pad structures 175A, 175B and 175C., respectively.

According to example embodiments, a method of manufacturing a semiconductor device may include an operation of forming fence structures 160 extending in a first direction (X-direction) and spaced apart from each other in a second direction (Y-direction), and accordingly, the landing pad structure 175 may be physically separated into a first landing pad structure 175A, a second landing pad structure 175B, and a third landing pad structure 175C spaced apart from each other in the second direction (Y-direction).

According to example embodiments, a method of manufacturing a semiconductor device may include an operation of forming fence structures 160 of FIG. 8A, penetrating the landing pad structure 175, the metal-semiconductor compound layer 135, and the buried contact structure 130 after forming the landing pad structure 175 of FIG. 7A. Accordingly, since the landing pad structure 175 is formed prior to the process of forming the fence structure 160, the difficulty of the process of forming first and second conductive pad patterns 172 and 174 including different conductive materials on the conductive barrier layer 171 constituting the landing pad structure 175 may be reduced.

In addition, by forming the fence structures 160, the landing pad structure 175 may be formed as a first landing pad structure 175A, a second landing pad structure 175B, and a third landing pad structure 175C extending in the first direction (X-direction) and spaced apart in the second direction (Y-direction). Accordingly, the process operations for physically separating the landing pad structure 175 may be significantly reduced. Accordingly, through the method of manufacturing a semiconductor device according to example embodiments, a semiconductor device with improved reliability while improving process efficiency may be provided.

Referring to FIGS. 9A and 9B, a second mask pattern M2 may be formed on the landing pad structures 175. Using the second mask pattern M2, second trenches OPN2 for recessing the landing pad structure 175 may be formed.

The mask pattern M2 may be in the form of a line extending in a diagonal direction (for example, the second diagonal direction W2 of FIG. 2B) between the first direction (X-direction) and the second direction (Y-direction), and the second mask pattern M2 may include second openings that are spaced apart from each other in the second direction (Y-direction) and expose the upper surface of the landing pad structure 175. The landing pad structure 175 exposed through the second openings may be recessed to form second trenches OPN2. Through the respective second trenches OPN2, the cross sections of the conductive barrier layer 171, the first conductive pad pattern 172, and the second conductive pad pattern 174, the upper end of the spacer structure 150, and one cross section of the fence structure 160 may be exposed.

The first landing pad structure 175A, the second landing pad structure 175B, and the third landing pad structure 175C are respectively, physically separated through the second trenches OPN2, and may include a 1-1 landing pad structure 175_1, a 1-2 landing pad structure 175_2, and a 1-3 landing pad structure 175_3 spaced apart in the first direction (X-direction). The 1-1 landing pad structure 175_1, the 1-2 landing pad structure 175_2, and the 1-3 landing pad structure 175_3 may respectively be formed to correspond to a buried contact structure 130. The second trench OPN2 may be referred to as a pad separation trench.

Next, referring to FIG. 3A, an insulating material may be formed in the second trenches OPN2 to form pad separation patterns 176. By forming a capacitor structure 180 on the landing pad structures 175, the pad separation patterns 176, and the fence structure 160, the semiconductor device 100 of FIG. 1 may be manufactured.

As set forth above, the semiconductor devices according to example embodiments may include a metal-semiconductor compound layer on a buried contact structure connected to a cell active region, and conductive pad patterns including two or more kinds of metal materials on the metal-semiconductor compound layer, thereby providing a semiconductor device having improved electrical characteristics and reliability.

In the method of manufacturing a semiconductor device according to example embodiments, since landing pads may be separated with a minimum number of process operations, thereby providing a method of manufacturing a semiconductor device with increased process efficiency.

In example embodiments, a method of manufacturing a semiconductor device may include preparing a substrate including a cell area and a peripheral circuit area; forming a cell gate structure extending in a first direction within the cell area of the substrate; forming bit line structures extending in a second direction, intersecting the first direction, and spaced apart from each other in the first direction, and spacer structures covering both sidewalls of the bit line structures, on the cell area of the substrate; forming a buried contact structure connected to a cell active region of the substrate, in a lower portion of a space between the spacer structures on the substrate; forming a metal-semiconductor compound layer on the buried contact structure; forming a landing pad structure covering an upper portion of the space between the spacer structures and the bit line structure, on the metal-semiconductor compound layer; and forming a fence structure penetrating the landing pad structure, the metal-semiconductor compound layer, and the buried contact structure, extending in the first direction, and overlapping the cell gate structure in a vertical direction intersecting the first direction and the second direction.

In example embodiments, the forming the cell gate structure may include forming a word line trench from an upper surface of the substrate; and forming a cell gate dielectric film in the word line trench, a cell gate electrode layer on the cell gate dielectric film, and a cell gate capping layer on the cell gate electrode layer.

In example embodiments, the forming the fence structure may include forming a fence structure trench penetrating the landing pad structure, the metal-semiconductor compound layer, the buried contact structure, and a portion of the cell gate capping layer; and filling an insulating material in the fence structure trench.

In example embodiments, the method of manufacturing a semiconductor device may further include forming pad separation patterns that are buried from an upper surface of the landing pad structure toward the spacer structures formed on one sidewalls of the respective bit line structures.

In example embodiments, the forming the pad separation patterns may include forming a mask pattern extending in a diagonal direction between the first direction and the second direction on the landing pad structure; forming pad separation trenches by removing a portion of the landing pad structure from an upper surface of the landing pad structure exposed through the mask pattern and portions of the spacer structures formed on one sidewalls of the respective bit line structures; and forming an insulating material within the pad separation trenches.

According to example embodiments, the forming the landing pad structure may include forming a conductive barrier layer covering the metal-semiconductor compound layer, sidewalls of the spacer structures exposed through the upper portion of the space between the spacer structures, and the upper surfaces of the bit line structures; and forming a conductive pad pattern on the conductive barrier layer.

According to example embodiments, the conductive barrier layer and the conductive pad pattern may be in contact with the side surface of the fence structure.

In example embodiments, the method of manufacturing a semiconductor device may further include forming a peripheral gate structure on the peripheral circuit area of the substrate and peripheral gate spacers on both sidewalls of the peripheral gate structure; forming a peripheral interlayer insulating layer on the peripheral gate structure and the peripheral gate spacers; forming a peripheral contact plug penetrating the peripheral interlayer insulating layer and connected to the peripheral active region of the peripheral circuit area on one side of the peripheral gate structure; and forming a peripheral interconnection layer connected to the peripheral contact plug, on the peripheral interlayer insulating layer.

In example embodiments, the forming the peripheral contact plug may include forming a peripheral contact hole penetrating the peripheral interlayer insulating layer and exposing a portion of the peripheral circuit area of the substrate; forming a peripheral metal-semiconductor compound pattern on a lower surface of the peripheral contact hole; and forming a peripheral barrier layer on an upper surface of the peripheral metal-semiconductor compound pattern and a sidewall of the peripheral contact hole, and a peripheral conductive pattern on the peripheral barrier layer.

In example embodiments, the metal-semiconductor compound layer and the peripheral metal-semiconductor compound pattern may include the same material.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate including an active region;
a cell gate structure disposed within the substrate and extending in a first direction across the active region;
bit line structures intersecting the cell gate structure and extending in a second direction, intersecting the first direction;
spacer structures covering both sidewalls of the bit line structures;
a buried contact structure disposed in a lower portion of a space between the spacer structures, on the substrate, and connected to the active region;
a metal-semiconductor compound layer disposed on the buried contact structure;
a landing pad structure disposed in an upper portion of the space between the spacer structures, on the metal-semiconductor compound layer and the bit line structures; and
a fence structure extending in the first direction by penetrating through the buried contact structure, the metal-semiconductor compound layer and the landing pad structure, and overlapping the cell gate structure in a vertical direction intersecting the first direction and the second direction,
wherein the landing pad structure includes a conductive barrier layer disposed on side surfaces of the spacer structures protruding on the metal-semiconductor compound layer, and a conductive pad pattern disposed on the conductive barrier layer and in contact with the fence structure.

2. The semiconductor device of claim 1, wherein a side surface of the fence structure is in contact with a side surface of the buried contact structure, a side surface of the metal-semiconductor compound layer, and a side surface of the conductive pad pattern.

3. The semiconductor device of claim 1, wherein a lower surface of the fence structure is disposed at a level lower than a level of a lower surface of the buried contact structure.

4. The semiconductor device of claim 1, wherein the cell gate structure includes a cell gate trench within the substrate, a cell gate dielectric layer within the cell gate trench, a cell gate electrode layer on the cell gate dielectric layer, and a cell gate capping layer on the cell gate electrode layer, and
a lower surface of the fence structure is buried in the cell gate capping layer.

5. The semiconductor device of claim 1, further comprising a capacitor structure on the landing pad structure and the fence structure,
wherein an upper surface of the fence structure contacts a lower surface of the capacitor structure.

6. The semiconductor device of claim 1, wherein the fence structure has a width in the second direction that decreases downwardly.

7. The semiconductor device of claim 1, wherein the conductive pad pattern includes a first conductive pad pattern covering side surfaces of the spacer structures and an upper surface of each of the bit line structures, and a second conductive pad pattern on the first conductive pad pattern,
wherein the first conductive pad pattern includes a first conductive material, and
the second conductive pad pattern includes a second conductive material different from the first conductive material.

8. The semiconductor device of claim 7, wherein an upper surface of the first conductive pad pattern is disposed at a higher level than a level of the upper surface of each of the bit line structures.

9. The semiconductor device of claim 1, wherein the metal-semiconductor compound layer includes cobalt silicide (CoSiₓ).

10. The semiconductor device of claim 1, wherein the conductive barrier layer does not overlap with the cell gate structure in the vertical direction.

11. The semiconductor device of claim 1, further comprising a pad separation pattern recessing a portion of the landing pad structure and contacting the spacer structures,
wherein the pad separation pattern extends in a diagonal direction between the first direction and the second direction.

12. The semiconductor device of claim 1, wherein a width of the landing pad structure in the second direction decreases upwardly.

13. A semiconductor device comprising:
a substrate including an active region;
a cell gate structure disposed within the substrate and extending in a first direction across the active region;
bit line structures intersecting the cell gate structure and extending in a second direction, intersecting the first direction;
spacer structures covering both sidewalls of the bit line structures;
a buried contact structure disposed in a lower portion of a space between the spacer structures, on the substrate, and connected to the active region;
a landing pad structure disposed in an upper portion of the space between the spacer structures, on the buried contact structure and the bit line structures; and
a fence structure penetrating the buried contact structure and the landing pad structure and extending in the first direction, and overlapping the cell gate structure in a vertical direction intersecting the first direction and the second direction,
wherein a width of the fence structure in the second direction becomes narrower as it goes downwardly, and
a width of the landing pad structure in the second direction increases downwardly.

14. The semiconductor device of claim 13, wherein a lower surface of the fence structure is disposed at a level lower than a level of a lower surface of the buried contact structure.

15. The semiconductor device of claim 13, wherein the landing pad structure includes a conductive barrier layer on the sidewalls of the bit line structures protruding on the buried contact structure, and a conductive pad pattern disposed on the buried contact structure and the conductive barrier layer and in contact with the fence structure.

16. The semiconductor device of claim 13, further comprising a metal-semiconductor compound layer between the buried contact structure and the landing pad structure,
wherein the fence structure penetrates the metal-semiconductor compound layer.

17. A semiconductor device comprising:
a substrate including a cell area and a peripheral circuit area;
a cell active region disposed on the substrate in the cell area;
a peripheral active region disposed on the substrate in the peripheral circuit area;
a cell gate structure disposed within the substrate in the cell area and extending in a first direction across the cell active region;
bit line structures intersecting the cell gate structure and extending in a second direction, intersecting the first direction;
spacer structures covering both sidewalls of the bit line structures;
a buried contact structure disposed in a lower portion of a space between the spacer structures and on the cell gate structure, on the substrate, and connected to the active region;
a metal-semiconductor compound layer on the buried contact structure;
a landing pad structure disposed in an upper portion of the space between the spacer structures, on the metal-semiconductor compound layer and the bit line structures;
a fence structure extending in the first direction while penetrating the buried contact structure, the metal-semiconductor compound layer, and the landing pad structure, and overlapping the cell gate structure in a vertical direction intersecting the first direction and the second direction;
a peripheral gate structure disposed on the substrate in the peripheral circuit area;
a peripheral contact plug disposed adjacent to the peripheral gate structure and connected to the peripheral active region; and
a peripheral interconnection layer on the peripheral contact plug,
wherein the landing pad structure includes a conductive barrier layer disposed on side surfaces of the spacer structures protruding on the metal-semiconductor compound layer, and a conductive pad pattern disposed on the conductive barrier layer and in contact with the fence structure, and
the peripheral contact plug includes a peripheral conductive pattern, a peripheral barrier layer surrounding a side surface and a lower surface of the peripheral conductive pattern, and a peripheral metal-semiconductor compound pattern on a lower surface of the peripheral barrier layer.

18. The semiconductor device of claim 17, further comprising a peripheral insulating layer disposed on the peripheral gate structure and in contact with a lower surface of the peripheral interconnection layer,
wherein the conductive pad pattern includes a first conductive pad pattern covering side surfaces of the spacer structures and an upper surface of each of the bit line structures, and a second conductive pad pattern on the first conductive pad pattern,
the peripheral conductive pattern and the first conductive pad pattern include a first conductive material, and
the peripheral interconnection layer and the second conductive pad pattern include a second conductive material different from the first conductive material.

19. The semiconductor device of claim 18, wherein the first conductive material includes titanium nitride (TiN), and
the second conductive material includes tungsten (W).

20. The semiconductor device of claim 17, wherein the metal-semiconductor compound layer and the peripheral metal-semiconductor compound pattern include cobalt silicide (CoSiₓ).
